(19) United States
(12) Patent Application Publication
(10) Pub. No.: US 2003/0060020 A1
(43) Pub. Date: Mar. 27, 2003

(54) Method and apparatus for finishing substrates for wafer to wafer bonding

(75) Inventors: Hans Walitzki, Portland, OR (US); Claudian Nicolesco, Portland, OR (US); Thomas J. Magee, Lake Oswego, OR (US); Howard W. Hogle, Portland, OR (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Silicon Evolution, Inc., Vancouver, WA

(21) Appl. No.: 09/976,452

(22) Filed: Oct. 11, 2001

Related U.S. Application Data
(60) Provisional application No. 60/239,992, filed on Oct. 12, 2000.

(51) Int. Cl. H01L 21/30; H01L 21/46; H01L 21/302; H01L 21/461

(52) U.S. Cl. 438/455; 438/692; 438/693

(57) ABSTRACT

The present invention relates to the manufacture of substrates for semiconductor device manufacturing particularly for applications that involved wafer-to-wafer bonding for SOI or MEMS structures. Although previous techniques have been applicable to single crystal wafers using bonding and annealing, the current techniques offer the unique capability of utilizing lower cost semiconductor materials, even when they contain dislocations or other growth associated stress fields; such as poly or multi-crystalline silicon and seed, or tail ends of CZ or FZ grown ingots. This invention provides a means of obtaining superior global and local flatness, along with nanoscale roughness variations across the surfaces so that cost and throughput are optimized.

This application claims the benefit of U.S. Provisional Patent Application No. 60/239,992 filed on Oct. 12, 2000.

### BACKGROUND OF THE INVENTION

The process sequence to manufacture semiconductor wafers for boules (ingots) of crystalline material usually contains process steps like slicing (ID or MWS), grinding and or lapping, etching, and chemical-mechanical polishing (single or multiple steps). Polishing is performed by simultaneous chemical and mechanical removal of surface layers. While this process is well established for high quality, stress and defect free monocrystalline material, the chemical etching occurring during polishing reveals (delineates) stress fields, dislocation loops, impurities and grain boundaries when applied to non stress-free or multi-crystalline ingots. This creates and leaves surfaces features that make this kind of substrate unsuitable for any application that requires flat and smooth wafer surfaces, like in wafer-to-wafer bonding for SOI or MEMS applications. A process that creates flat and smooth surfaces on multi or poly-crystalline or amorphous materials would result in significant cost saving in the manufacture of SOI or MEMS structures.

It has been well established that the roughness of a surface stays an integral part in the bonding efficiency of semiconductor wafers. It has been shown that microroughness will lead to void, generations and that stress in the bonding interface arising from local elastic deformation can be related to surface topography. Recently, it has been shown that the average surface heights of asperities were the dominant factor influencing bonding, whereas long spatial wavelength the structure was less important. To eliminate roughness and grind damage, traces from surface requires chemical etching, Double Side Polishing (DSP) and final Chemical Mechanical Polishing (CMP) subsequent to grinding. When applied to poly-crystalline substrates, such procedures are less than effective, because of selective etching at grain boundaries.

The present invention provides a technique for processing wafers that are cut from ingots and have a large degree of unevenness (waviness), roughness and surface damage in the range of several μm up to 50 μm in a sequence of process steps that avoid any chemical etching and subsequently improve the evenness and reduce surface damage with a minimum total loss of substrate material. The absence of chemical etching combined with minimal stock removals and the capability to shape the substrate as required make this process also very useful for regular semiconductor wafers including, but not limited to, monocrystalline silicon wafers or GaAs or InP or Li3TaO4.

### SUMMARY OF THE INVENTION

According to the present invention, a technique is provided for the preparation of “Hyperflat” surfaces on semiconductor materials using a sequence of purely mechanical removal steps. This technique eliminates the chemical etching / polishing that is usually applied in the manufacture of semiconductor wafers, improving the macroscopic and microscopic smoothness of the substrate and reducing the environment hazards of conventional wafer processing.

In one embodiment, the present invention provides a method for fabricating silicon substrates, including substrates made from non poly-crystalline materials. The method provides a smooth, flat surface on at least the front side of the wafer characterized by a roughness of less than 20 Angstroms obtained by a sequence of mechanical grinding and polishing steps. The final polishing steps are performed on commercially available equipment, which was originally developed to give optical lenses a specific shape. The polishing compound is known as Magneto-Rheological-Fluid (MRF). Polishing occurs when the constitution of the compound is modified by the amplitude of a local magnetic field. The method allows a locally variable amount of surface layer to be removed based on prior measurements of the substrate's geometry. Thus the shape of the wafer can be trimmed as desired and deficiencies from prior, rougher wafer shaping steps are removed.

In another embodiment of the invention a silicon overlayer (SOI) can be trimmed to obtain a thinner layer with tighter tolerance control than the conventional bonding/backgrinding/polishing process for SOI can achieve.

In yet another embodiment, the MRF polishing procedure can be used on thin, fine-grained poly-crystalline films deposited on low cost large-grained poly-substrates that have been exposed to two stage grinding prior to film deposition.

In still another embodiment, the MRF polishing process can be used to smooth 2-stage edge-ground, bonded structures to eliminate variations responsible for particle accumulations and micro-cracking at the edge zones.

### BRIEF DESCRIPTION OF THE DRAWINGS

FIG. 1 is a schematic representation of an MRF Polishing Apparatus in accordance with the present invention.

### DESCRIPTION OF THE SPECIFIC EMBODIMENTS

Case 1

In one embodiment, the sawn substrate is first ground on one or both surface layers on commercially available high speed surface grinder using a relatively coarse (example: mesh 500) grinding wheel. For the first grinding step the substrate is supported by a chuck using a soft interface layer (example Poly-Urethane pad as commonly used as polishing pad) to compensate for the typical waviness of a sawn wafer. The wafer is then flipped and the opposite side is ground. The use of a soft interface layer is optional for this step. The stock removal for both grinding steps is chosen to be at least the arithmetic sum of peak-to-valley waviness, total thickness variation and sub-surface damage (typ. 20- 30 μm per side). The wafer is then ground again on at least one side using a finer grinding wheel (example mesh 2000) removing typ. 10 μm of material (approx. the depth of lattice damage created by the coarse grinding wheel). This side is then again ground with an even finer grinding wheel (mesh size 2000 or larger).

At this stage the wafer will be very flat (TTV <1 μm) and have a surface roughness of <100 A. The total stock removal of all process steps was less than 50 μm, about half of the commonly required removals in conventional substrate processing. No chemical etching was used after slicing and after grinding. This significantly reduces the potential environmental impacts from strong etchants (HF, HNO3, KOH, TMAH) that are commonly used for this purpose.

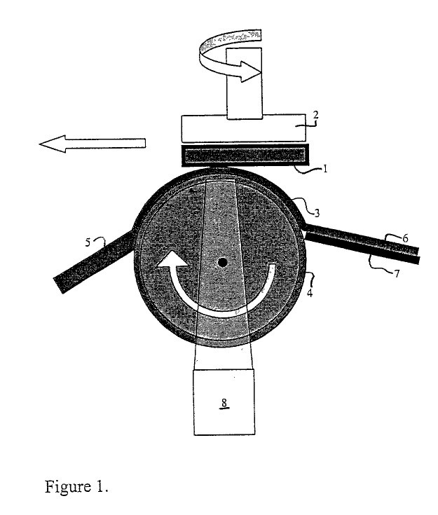

In an embodiment of the invention, a MRF polishing in a commercial apparatus (as shown schematically in FIG. 1) is used as a finishing step to create the final surface of the substrate. Shown in the sole figure are a substrate 1, a substrate holder 2, a MRF fluid (slurry) 3, a polishing wheel 4, a slurry supply nozzle 5, a slurry 6, a slurry catch pan 7, and an electromagnet 8. MRF is a technique for precision shaping and polishing of optical lenses and mirrors. A feature of MRF is the slurry composed of FeC spheres in water with optional abrasives and additives.

Depending on the amount of material to be removed and the substrate material abrasives like diamond powder, ceramics or other may be added to increase the MRF polishing removal rate.

For a tight control of geometry, prior to MRF, the wafer may be mapped and MRF can be applied to trim the wafer to the desired shape by varying the dwelling time accordingly.

Following MRF, the substrate is then cleaned on commercial wafer scrubbers. A final surface conditioning step using dilute HF, SC1 and/or SC2 followed by a rinsing/drying step creates a surface condition similar to conventionally polished wafers.

Alternatively, a scrubbing step may be performed after the dilute HF, SC1/SC2 step or may even be omitted.

Alternatively, scrubbing followed by a dilute HF / Ozone step may be used to create a clean, hydrophilic surface that is commonly required.

Since no chemical etching is employed throughout the entire process, no bulk inhomogeneities are delineated. Substrates (Example: 200 mm silicon substrate) with global and local thickness variation of <0.1 μm over the entire surface and a roughness of <10 A were obtained using mono-crystalline as well as multi-crystalline silicon ingots. Also, the absence of etching drastically reduces the costs associated with handling of hazardous materials and waste.

Case 2

In another embodiment, particularly for applications that require a RMS surface roughness of <1-2 A, MRF is followed by a very brief CMP (chemical-mechanical planarization) polishing step performed on conventional, commercially available CMP equipment using conventional polyurethane (PU) pads and silica based slurries. However, compared to the conventional use of this technique after chemical (rough) polishing, the process time is largely reduced (example from 5-10 min to <1 min). Therefore the detrimental tendency of CMP to delineate stress fields and other bulk inhomogeneities is strongly suppressed and the economy of this process is significantly increased. The wafers obtained from this additional final CMP polishing step reveal a similar surface condition as conventional wafers, yet maintain the superior flatness characteristics because the short exposure to the CMP process will not change the global and local flatness of the substrate.

Case 3

In another embodiment of our invention, the wafer is mounted on a chuck that also allows the MRF finishing step to also act on the substrate's edge, thus providing a front- and edge polished substrate in a single operation.

Case 4

In another embodiment of our invention the MRF technique is applied after bonding and backgrinding of a bonded silicon wafer pair. In this case, two polished substrates are bonded (see elsewhere) and annealed with one or more optional insulating layers in between. A grinding step (or multiple grinding steps) reduces the thickness of one of the substrates to a thickness larger than the desired final thickness plus the damage depth of the grinding step. MRF then removes this damaged layer and optionally trims the thickness where necessary to obtain a tighter thickness tolerance after mapping the layer thickness.

When combined with the edge polishing feature (case 3) MRF will also produce a sharp defined edge zone for the thin top layer.

Case 5

Another embodiment of the invention may be used to make very thin substrates for the top layer of a bonded wafer pair. It is very difficult if not impossible to obtain wafers of less than 400 μm with global and local flatness and roughness sufficient for wafer bonding. In one embodiment, an ingot is cut on a Multi-Wire Saw to obtain thin wafers (example 350 μm). Grinding (see case 1) and MRF produces flat, smooth thin wafers with approximately 300 μm thickness. During all process steps following slicing the substrate is supported by a rigid chuck, which reduces the risk of breakage of thin wafers significantly.

Compared to conventional processing, much less material is removed in the back-grinding step after bonding and annealing. This technique therefore yields in twice as many wafers from expensive, high quality ingot materials that are commonly required for the top layer in an SOI or similar wafer, a significant costs savings factor. An optional very brief final CMP step may be added to achieve identical characteristics as comparable polished wafers if needed.

Case 6

In another embodiment, MRF is used on a ground substrate (mono or multicrystalline), which is covered by a thin (example 1-2 μm) film, deposited by conventional CVD or sputtering processes. This film fills-in any grooves or other grinding artifacts that would otherwise require a larger removal. MRF is then used as a final finishing step to reduce microroughness of the poly-crystalline layer.

### EXAMPLE

We conducted a series of tests using the methods outlined in the current invention. The sample types and preparation conditions are summarized in Table 1. Using a variety of conditions for MRF, we processed wafers and subsequently obtained roughness measurements on a Chapman MP2000+ laser scanning instrument. A summary of data obtained at three points (center, R/2 and edge) before and after MRF polish is shown in Table 2. It is apparent that the MRF polish steps reduces the surface roughness on single or poly-crystalline samples under a variety of surface finish conditions. Both single and poly-crystalline samples exposed to a two step (coarse+fine) grind finish and subsequently subjected to MRF polishing show dramatic improvements in surface roughness, resulting in surfaces that are compatible in roughness to DSP/FP wafers. In addition, the polycrystalline FG samples show no evidence of delineated grain boundaries after MRF and under appropriate parameter changes during MRF, no visible grind marks were retained on the surface.

TABLE 1
Summary of Tested Samples and Conditions Before MRF Polish

| Conditions | Crystal | Preparation |
|---|---|---|
| 1 | Single | DSP*/noFP* |
| 2 | Single | DSP/noFP |
| 3 | Poly-crystalline | DSP/noFP |
| 4 | Single | DSP/noFP |
| 5 | Poly-crystalline | FG* |
| 6 | Poly-crystalline | FG |
| 7 | Poly-crystalline | FG |
| 8 | Single | FG |
| 9 | Single | Epilayer |
| 10 | Single | Epilayer |

*FG = Fine Grind after Coarse Grind, DSP = Double Side Polish, FP = Final Polish

TABLE 2
Summary of Surface Roughness Data Before and After MRF Polish on
Prepared Samples

| | | Before MRF | | | After MRF | | |
|---|---|---|---|---|---|---|---|
| Crystal | Preparations | center | R/2 | edge | center | R/2 | edge |
| Single | DSP/noFP | 4.98 | 5.18 | 3.98 | 9.05 | 3.58 | 3.30 |
| Poly-crystalline | FG | 52.30 | 98.00 | 64.68 | 29.49 | 16.83 | 7.14 |
| Poly-crystalline | FG | 97.61 | 97.61 | 91.19 | 5.62 | 3.44 | 3.01 |
| Poly-crystalline | FG | 65.88 | 123.27 | 140.01 | 3.98 | 3.89 | 3.88 |
| Single | FG | 118.56 | 176.46 | 132.59 | 5.63 | 2.94 | 4.58 |

Appendix A

The following table compares the process sequences of conventional substrate fabrication with the various embodiments of our invention. All of the examples yield in substrates with favorable global and local thickness control and smooth damage free surfaces on mono- and/or polycrystalline substrates. The best choice is merely determined by the type of material processed and economic considerations in mass manufacturing.

TABLE
Process comparison conventional vs. MRF

| Process Step: | Conventl. | Case 1 | Case 2 | Case 3 | Case 4 | Case 6 | Remarks |
|---|---|---|---|---|---|---|---|
| Ingot (Mono/Poly) | Mono | Mono/Poly | Mono/Poly | Mono/Poly | Mono/Poly | Mono/Poly | |
| Slicing | yes | yes | yes | yes | yes | yes | MWS prefered |
| (IDS or MWS) | | | | | | | |
| Edge Grinding | yes | yes | yes | yes | yes | yes | |
| f/s and b/s Grinding | optional | 2-step | 2-step | 2-step | 2-step | 2-step | 2*15 + 10 μm |
| Lapping | ˜60 μm | no | no | no | no | no | |
| Etching | 30-40 μm | no | no | no | no | no | |
| HF/HNO3 or KOH | | | | | | | |
| Edge Polishing | opt. ECMP | opt. | opt. | MRF | opt. | opt. | |
| Rough Pol f/s | min 15 μm | no | typ. 3 μm | opt., 3 μm | opt., 3 μm | opt., 3 μm | Chem./Mech. |
| Rough Pol b/s | opt. 2-15 μm | opt., 2 μm | typ. 3 μm | opt., 2 μm | opt., 2 μm | opt., 2 μm | Chem./Mech |
| Intermediate Pol f/s | typ. 2 μm | no | no | no | no | no | Chem./Mech |
| MRF | opt. | 1-2 step | 1 step | 1 step | 1 step | 1 step | |
| Final CMP | typ. 5-10 min | opt. | typ. 1 min | opt. | opt. | opt. | |
| Cleaning | | | | | | | |
| scrubbing | opt. | opt. | opt. | opt. | opt. | opt. | |
| HF/SC1/SC2 | yes | opt. | opt. | opt. | opt. | opt. | |
| HF/O3 | opt. | opt. | opt. | opt. | opt. | opt. | |

What is claimed is:

1. A method for producing low roughness semiconductor wafer surfaces for bonding in SOI applications, comprising:
providing a polycrystalline or single crystal semiconductor wafer;
exposing a surface of said wafer to a grinding process using a fine grit grinding wheel;
subjecting the wafer to Magneto-Rheological-Fluid (MRF) polishing; and
cleaning the wafer of particles and residues in a scrubbing apparatus.

2. The method of claim 1, further comprising providing additives of glycol to reduce subsurface damage during the grinding process.

3. The method of claim 1, further comprising chemical etching after grinding.

4. The method of claim 1, further comprising a CMP finish step.

5. The method of claim 1, further comprising:
bonding two wafers and thereafter subjecting said two wafers to DSP;
grinding at least one side of said bonded wafers; and
performing an MRF polish.

6. A method for producing thin top layers of a substitute bonded pair for bonding in SOI applications, comprising:
providing a polycrystalline semiconductor wafer;
exposing a surface of said wafer to a grinding process using a fine grit grinding wheel;
subjecting the wafer to Magneto-Rheological-Fluid (MRF) polishing;
subjecting the wafer to a Chemical Mechanical Polishing (CMP) finish step; and
cleaning the wafer of particles and residues in a scrubbing apparatus.

7. The method of claim 6, further comprising:
depositing a thin poly-crystalline layer on the substitute surface by CVD or sputtering; and
exposing said layers to MRF polishing to remove microroughness.

8. A method of producing smooth, defect-free edge regions of semiconductor wafers by:
exposing edges to an edge grind in the presence of glycol; and
exposing edges subsequently to a MRF polish to reduce roughness and eliminate subsurface damage.

9. Application of procedures described in claims where material is composed of silicon.

10. Application of procedures described in claims where material is composed of gallium arsenide.

11. Application of procedures described in claims where material is composed of lithium tantalate.

12. Application of procedures described in claims where the slurry used for MRF polishing of semiconductor materials contains abrasives in an aqueous solution also containing FeC particles. These abrasives can be any one or combination of the following materials: Diamond powder, SiC powder, A12O3 powder, metal oxide powders. The grain size of the abrasive powders is chosen to obtain the best compromise between surface finish, subsurface damage and requirement for post MRF final polishing by CMP.

13. Application of procedures described in claims where the wafer thickness is mapped prior to MRF and the removals are varied locally to compensate for thickness variations while maintaining a minimum removal to completely remove grind damage.

14. Application of procedures described in claims where the thickness of a SOI or SOS top layer is mapped prior to MRF and the removals are varied locally to compensate for thickness variations while maintaining a minimum removal to completely remove grind damage.
